(19) United States
(12) Patent Application Publication
(10) Pub. No.: US 2026/0206490 A1
(43) Pub. Date: Jul. 16, 2026

(54) Thermo-Cell Configuration

(71) Applicants: New Jersey Institute of Technology, Newark, NJ (US); RTX Corporation, Arlington, VA (US)

(72) Inventors: Haim Grebel, Newark, NJ (US); Robert Darling, Arlington, VA (US)

(73) Assignees: New Jersey Institute of Technology, Newark, NJ (US); RTX Corporation, Arlington, VA (US)

(21) Appl. No.: 19/444,774

(22) Filed: Jan. 9, 2026

Related U.S. Application Data
(60) Provisional application No. 63/743,871, filed on Jan. 10, 2025.

(51) Int. Cl. H10N 10/17; H01M 10/0525; H01M 10/0585

(52) U.S. Cl. CPC H10N 10/17; H01M 10/0525; H01M 10/0585

(57) ABSTRACT

A thermo-cell includes a first electrode and a second electrode defining a space therebetween with an electrolyte disposed within the space. At least one p-type membrane is positioned in the space and facing the first electrode and at least one n-type membrane is positioned in the space and facing the second electrode. The p-type membrane and the n-type membrane are physically separated and create an electric field gradient through the space for the selective transport of ions within the electrolyte. A system including a plurality of such thermo-cells arranged to be electrically coupled is also provided.

### CROSS REFERENCE TO RELATED APPLICATION(S)

The present application is non-provisional application which claims priority from U.S. Provisional Application No. 63/743,871 filed on Jan. 10, 2025, the entire disclosure of which is incorporated herein by reference.

### FIELD OF USE

The present disclosure relates to a novel construct of thermo-cells that increases cell output and efficiency as compared to current state of the art thermo-cells. More particularly, it relates to a thermo-cell that utilizes a membrane, separating two electrodes, which achieves directed transport of ions so as to enhance the current and voltage outputs of the thermo-cell.

### BACKGROUND OF THE INVENTION

It is well known that a “thermo-cell,” also called a thermo-electrochemical cell, is a device that converts low-grade heat into electricity by utilizing temperature-dependent redox reactions, essentially harnessing the difference in temperature between two points to generate power. While thermo-cells hold promise for harvesting waste heat, their current efficiency is generally considered low compared to other power generation methods.

Waste heat, such as from geothermal sources or in industrial power plants, is a major energy source that is extremely underutilized. For example, currently about 90% of the world's power is generated by heat engines that use fossil fuel combustion as a heat source and operate at only ~30-40% efficiency. The development of efficient thermo-electrochemical devices could enable harvesting of some of this waste heat for use in low voltage applications such as lighting, communications, human medical applications (e.g., pacemakers), Internet-of-Things (IoT) devices, and wearable devices. Even capturing some of the waste heat generated from internal combustion engines could provide electricity for functions such as on-board controls. Many sources of waste heat are continuous, which is an advantage over other renewable energy sources.

As such, long-lived, safe, compact, and reliable energy harvesters are needed to power future medical and Internet-of-Things (IoT) devices. Waste heat is an abundant resource that is recovered to generate electricity in various commercial and industrial applications. However, efficient recovery becomes more challenging as hot sink temperature decreases. This is shown in FIG. 1, which plots Carnot (maximum) efficiency versus hot sink temperature. While waste heat equivalent to ~70% of U.S. energy consumption is available below 150° C. and ~30% of this could theoretically be converted to work, currently available heat-to-electricity technologies cannot convert this heat to power economically. The challenge is even greater for medical and IoT devices because hot side temperatures are low and temperature differences are small. Therefore, there is a strong need and large potential reward for pushing past the limits of current heat-to-electricity technologies.

Thermo-cells convert a difference in temperature between a hot and a cold electrode into a sustained voltage difference (and hence, a sustained electronic current flow) to harvest thermal energy. Thermo-cells are ideally suited to recovering waste heat at low temperatures (Tₕₒₜ≤50° C.) and low temperature difference ranges (ΔT≤20° C.) that may be present in human medical applications or wearables, for example, in a manner far superior to conventional thermoelectrics.

Thermo-electrochemical devices allow the direct conversion of thermal energy to electrical energy. Thermo-electrochemical cells, (also sometimes termed thermogalvanic cells, thermo-cells, thermal cells, galvanic thermo-cells, electrochemical thermocouples, or galvanic thermocouples) produce electrical energy by utilizing the temperature dependence of electrochemical redox potentials. Within the cells there are two electrodes, held at different temperatures. This temperature difference generates a potential difference between the electrodes, thereby allowing the heat to be converted to electrical energy. The driving force for the thermo-cell is the change of entropy from the high temperature reservoir to the low temperature sink, while chemical and thermal gradients drive the movement of redox species within the thermo-cell and prevent buildup of oxidized/reduced species at the electrodes. The magnitude of the voltage that can be induced in response to a temperature difference across a material is given by the so-called Seebeck coefficient, S.

If the cell contains a redox system A+ne⁻<=>B, then the temperature dependence of the electrochemical redox potentials is given by the Seebeck coefficient, S, such that: S=ΔV/ΔT=ΔS_{B,A}/nF, where V is the electrode potential, T is the temperature, n is the number of electrons involved in the redox reaction, F is Faraday's constant, and S_{B,A} is the reaction entropy for the redox couple measured in microvolts per Kelvin. The efficiency of a thermoelectric material or device can be described by the Figure of Merit, ZT, defined as the ratio of the desired energy gain to the energy that is input, i.e., the thermal efficiency η equals the ratio of the network output to the heat added at high temperature, where: ZT=S²σ/κ, where σ is the electrical conductivity and κ is the total thermal conductivity.

One of the earliest thermo-cells, the Ag|AgNO₃|Ag thermo-cell, was first reported in the 1890s, and there has since been a range of different metal electrodes, solid electrolytes, and liquid electrolytes investigated. In this archetypal system, the reaction at the anode (hot) is Ag→Ag⁺+e⁻. The Ag⁺ then moves through the electrolyte from the hot to cold side, where the reaction at the cathode is Ag⁺+e⁻→Ag. In this system, the metal of the anode is being consumed, and therefore the hot and cold side of the cell must, at some point, be reversed to allow further operation of the cell. A thermo-cell using solid AgI and gaseous I₂ was patented in 1957 (see U.S. Pat. No. 2,890,259), and a range of other gases and electrolytes have also been trialed.

These devices can theoretically be run continuously; however they use gas electrodes and often require high temperatures. There is also literature on the use of concentration cells (where the cathode and anode are placed in electrolyte solutions of different concentrations, such as strong and weak acid). As these systems can be thermally regenerated, they are sometimes referred to as thermo-electrochemical systems.

In the 1990s, Opallo reported studies on the electrode reactions of various redox couples in “frozen” electrolytes, i.e., salt hydrates taken below their melting point, (Opallo, M. J. Solid State Electrochem. 1998, 2, 347; Opallo, M. J. Electroanal. Chem. 1995, 399, 169; Opallo, M. J. Electroanal. Chem. 1996, 418, 91; Opallo, M. J Electroanal. Chem. 1996, 411, 145; Opallo, M. J. Electroanal. Chem. 1998, 446, 39; Opallo, M. J. Electroanal. Chem. 1998, 444, 187), and the change in the electrochemical potentials of these redox couples with temperature was described. However, these constructions never progressed to be realized as thermo-electrochemical cells.

Some solid-states thermoelectric devices utilized alternating p-type and n-type semiconductor materials, which commonly have Sₑ of a few 100 μν/K, can be extremely expensive, and are suitable only for small scale, niche applications or those utilizing extremely high temperatures. There has been considerable research into thermoelectric materials (e.g., Bi₂Te₃) over the last four decades, but these have achieved a maximum ZT of only ca. 1, which is generally not sufficient to make up for the high materials costs, particularly for lower temperature applications. This apparent limit to ZT for bulk materials is a result of the fact that materials with a high electrical conductivity also have a high thermal conductivity, and the interdependence of these factors makes improvement of ZT challenging. Research into further optimizing the performance of these devices relies on manipulating the materials at the nanoscale. In recent years there have been significant advances in ZT using nanomaterials, which have allowed ZT of up to 3.2, at a 300° C. temperature difference. However, the high ZT values achieved recently using nanoscale materials, e.g., thin films or nanowires, are not yet practical for industrial-scale commercial use because they are fabricated by techniques which are expensive and unsuitable for scale-up, such as atomic layer deposition.

U.S. Pat. No. 6,838,208 (De Crosta et al.) discloses the use of a modified thermal concentration galvanic cell for conversion of heat to electrical energy, has half-cells with metallic and inert electrodes, and electrolyte having metal or metallic salt electrode solution. One of the disadvantages of this type of cell is that one half of the cell contains a chemically active electrode (metal electrode) which undergoes oxidation while the other half is a concentration cell comprising a non-active electrode. Serious degradation of materials or cell components can occur due to oxidation of the metal electrode and metal salt electrolyte solution.

U.S. Pat. No. 4,376,155 (Peck) describes a thermal galvanic cell which works on the principal of establishing a heat gradient along the electrode as well as across it. However, this type of cell has the disadvantage that it includes electrode materials that are at least in part comprised of a conductive metal and there is an inherent risk of leakage because the electrolyte is a liquid.

U.S. Pat. No. 3,441,441 (Iverson) discloses the use of sodium salt mixtures as the electrolyte for galvanic cells. Specifically, it discloses the chemical reaction of the cathode and anode materials, Na⁺ and Hg⁺, and migration of Na⁺ ions through the electrolyte. Thus, the electrolyte is likely to be efficient in transporting the ions across, stable in high temperature, and not prone to leakage.

U.S. Pat. No. 4,396,690 (Gordon et al.) relates to a device for the simultaneous conversion of light energy into electrical energy and thermal energy using a liquid-junction semiconductor photoelectrochemicalcell (PEC).

U.S. Pat. No. 5,310,608 (Ishizawa et al.) discloses the use of two half cells separated by an impermeable membrane that stops a redox couple passing between the two halves of the cell. One half of the device is heated and the other is not, thus forming a concentration gradient. When the heat is subsequently removed, they function as concentration cells where the energy is stored via a concentration gradient, until needed. However this type of device has the disadvantage that it does not continuously produce electrical energy but instead stores energy for later use.

U.S. Pat. No. 5,487,790 (Yasuda et al.) relates to an electric power generating element for converting low temperature heat to electricity, the element including a positive electrode and a negative electrode composition based on polyethylene glycol. More specifically, in an electric power generating element, either the positive or negative electrode includes a composition containing an organic compound as a main agent. The positive electrode has an electrically conductive substance so that relatively low-temperature thermal energy is efficiently converted to electric energy. Polyethylene glycol is employed as the organic compound, and graphite or a graphite composition is employed as the conductive substance. Salt providing ionic conductivity may be added to the organic compound or polyethylene glycol, and the negative electrode may be formed of a metal having an ionization tendency as large as or larger than copper or a composition of the metal. One of the disadvantages of this type of element is that it uses a metal based electrode that is oxidized during use.

U.S. Pat. No. 10,840,426 (Carroll et al.) discloses a thermoelectric apparatus having at least one p-type layer coupled to at least one n-type layer to provide a pn junction and an insulating layer at least partially disposed between the p-type layer and the n-type layer. The p-type layer includes carbon nanoparticles, and the n-type layer includes n-doped carbon nanoparticles. This type of an arrangement requires a np or pn junction at the hot side of the cell and is expensive and complicated to manufacture. In addition, the efficiency of this cell is limited.

In summary, the incumbent technologies for converting low-grade waste heat to electricity are organic Rankine cycles (ORCs) and thermoelectric generators (TEGs). Commercial TEGs use semi-conductor technology and are relatively cheap. Solid-state TEG technology has not boomed commercially, mainly because of the large area required to harvest low temperature heat. Thermogalvanic cells were proposed as thermoelectric generators 150 years ago but were discounted due to their low efficiency. Recent thermo-cells, which are the electrochemical version of solid-state TEGs, are two orders of magnitude more efficient than solid-state TEGs. This has been achieved by introducing capacitive effects to augment galvanic effects. Thermo-cells rely on abundant materials and offer flexible manufacturing and accommodation, for example around cold and hot pipes in buildings.

Despite the promising advantages of thermo-cells, the current state of the art has failed to produce a highly efficient thermo-cell that overcomes the above disadvantages. There is therefore a need in the art for a thermo-cell that has high efficiency for outputting voltage and current that may be utilized commercially, or show promising results to further commercialization.

### SUMMARY

Compared to conventional technology, as demonstrated by the above prior attempts, the present disclosure fulfills the above criteria and provides additional benefits that state-of-the-art systems cannot provide. Unlike the above prior methods and devices, the present methods and devices ensure reliable and efficient thermo-cells that, for example, deliver up to 10 fold the amount of efficiency as compared to the current state of the art thermo-cells. Further, by consistently achieving such efficiency levels, the present technology can surpass the current standard. This has the benefit of eliminating the issue of unreliable efficiency of current thermo-cells and reduces the use of expensive materials for the thermo-cell.

One aspect of the present methods and devices utilizes electrodes including charge collectors (e.g., solid copper, conductive carbon, or solid stainless steel), a so called p-type membrane facing one of the current collectors, a so-called n-type membrane facing the other current collector, where the charge collectors and their associated membranes are physically separated with an electrolyte positioned between them. An inert layer (e.g., a membrane or separator) may be included in the physical separation.

In one aspect, a thermo-cell is composed of two electrodes and an electrolyte. One electrode is hot while the other is kept cold. Asymmetry is created between the electrodes such that counter ions that flow in the thermo-cell have directional preference, enabled by the respective p-type and n-type layers, which boosts the cell's efficiency. In one aspect, the current is amplified by a factor of at least 6 and the voltage by more than 25%, with an overpower amplification close to 10.

In another aspect, an electrode or a membrane (e.g., polytetrafluoroethylene (PTFE), commonly sold under the trademark TEFLON) separates a positively (p-type) and negatively (n-type) doped membranes. These p-type and n-type layers create an electric field between them which allows for selectively transporting one type of ion over the other. For example, the p-type and n-type layer may be disposed on the surface of the PTFE membrane for ease of assembly within the thermo-cell. However, this membrane is not limited to PTFE and may be comprised of any filter material that withstands high temperature gradients and is non-reactive with the electrolyte.

In yet another aspect, a positively charged polymeric membrane, or p-type membrane, is achieved with polyvinylpyrrolidone (PVP) coated graphite powder and a negatively charged polymeric membrane, or n-type membrane, is achieved with polyetherimide (PEI) coated graphite powder. These layers create an electric field gradient between them and selectively transport one type of ions over the other. For example, by selectively transporting among Fe²⁺ and Fe³⁺ ions. This arrangement is an example of an “asymmetric thermo-cell,” as disclosed herein. In one aspect, the “asymmetric” term relates to the asymmetric ion concentration from one side of the thermo-cell to another resulting from the induced electric field gradient, and the term does not necessarily require the structure of the thermo-cell itself to be asymmetrical from one electrode to the other.

In one aspect, the present disclosure provides a thermo-cell. The thermo-cell may include a first electrode and a second electrode defining a space therebetween; an electrolyte disposed within the space; a p-type membrane positioned in the space and facing the first electrode; and an n-type membrane positioned in the space and facing the second electrode. Furthermore, the p-type membrane and the n-type membrane may be physically separated and create an electric field gradient through the space for the selective transport of ions within the electrolyte.

In accordance with some aspect of the thermo-cell, the p-type membrane may be a positively charged polymeric material that includes a first polymer disposed on a first substrate. Additionally, the n-type membrane may be a negatively charged polymeric material that includes a second polymer disposed on a second substrate.

In accordance with some aspect of the thermo-cell, the first polymer may include at least one of polyvinylpyrrolidone (PVP), polyacrylic acid (PAA), and polystyrene sulfonate (PSS), or polyvinylidene fluoride (PVDF); and the second polymer may include at least one of polyetherimide (PEI), poly(2-N-(dimethylaminoethyl)methacrylate (PDMAEMA), or PVDF.

In another aspect of the thermo-cell, the first substrate may include a graphite powder layer, and the second substrate may include a graphite powder layer.

In accordance with some aspects of the thermo-cell, the first polymer may be coated on the first substrate layer, and the second polymer may be coated on the second substrate layer.

In another aspect of the thermo-cell, the p-type membrane and n-type membrane may be physically separated by a separating membrane positioned in the space therebetween. For instance, the p-type membrane may be disposed on a first side of the separating membrane, and the n-type layer may be disposed on a second side of the separating membrane.

In another aspect of the thermo-cell, the n-type membrane may be disposed on a hot side of the thermo-cell, and the p-type membrane may be disposed on a cold side of the thermo-cell.

In another aspect, an apparatus may include aspects of the thermo-cell, where the thermo-cell may be arranged such that a temperature difference between the cold side and the hot side of the thermo-cell is in a range of less than 50° C.

In another aspect of the thermo-cell, a distance between the n-type membrane and p-type membrane may be in a range of 100 to 200 microns.

In another aspect of the thermo-cell, the p-type membrane and n-type membrane may be physically separated by a separation distance. Furthermore, a thickness of the p-type membrane and the n-type membrane may be in a range 20%-40% of a thickness of the separation distance.

In another aspect of the thermo-cell, the p-type membrane may include a first p-type membrane and a second p-type membrane, and the n-type membrane may include a first n-type membrane and a second n-type membrane.

In yet another aspect of the thermo-cell, the first p-type membrane, the first n-type membrane, the second n-type membrane, and the second p-type membrane arranged sequentially from the hot side to the cold side.

In another aspect of the thermo-cell, the first p-type membrane, the first n-type membrane, the second p-type membrane, and the second n-type membrane arranged sequentially from the hot side to the cold side.

In yet another aspect of the thermo-cell, the electrolyte may include at least one of potassium chloride (KCL), ferro/ferri cyanides, iron oxide (ii,iii), or polyethylene glycol (PEG).

In another aspect of the thermo-cell, the thermo-cell may have a Seebeck coefficient in a range of greater than 1.5 mV/K. For instance, the Seebeck coefficient may be in a range of greater than 1.5 mV/K to 17 mV/K.

In another aspect of the thermo-cell, the PVP coating on the graphite may be disposed on a surface of the graphite in a uniform manner, so as to provide a consistent positive charge distribution across the membrane. Similarly, the PEI coating on the graphite may be disposed on a surface of the graphite in a uniform manner, so as to provide a consistent negative charge distribution across the membrane.

In another aspect of the thermo-cell, the electric field gradient between the p-type and n-type membranes may selectively facilitate the transport of cations through the p-type membrane and anions through the n-type membrane.

In another aspect, a system for energy generation may include a plurality of the thermo-cells arranged to be electrically coupled.

The above aspects are further explained in the detailed description and accompanying figures.

### BRIEF DESCRIPTION OF THE DRAWINGS

The patent or application file contains at least one drawing executed in color. Copies of the patent or patent application with color drawing(s) will be provided by the Office upon request and payment of the necessary fee.

To assist those of skill in the art in making and using the disclosed composition and method, reference is made to the accompanying figures, wherein:

FIG. 1 plots Carnot (maximum) efficiency versus hot sink temperature.

FIG. 2 illustrates a conventional thermo-cell compared to a thermo-cell according to one aspect of the present disclosure including a 2-part membrane (i.e., n-p layers).

FIG. 3 illustrates a conventional thermo-cell compared to a thermo-cell according to another aspect of the present disclosure including a 4-part membrane (i.e., n-p-p-n layers).

FIG. 4(a) shows finite element simulations of electrolytic potential distribution within a 2 mm half-cell having a central membrane in accordance with an aspect of the present disclosure, in which the cold electrode is on the left and the hot electrode is on the right and one ion species is diffusing between them.

FIG. 4(b) shows finite element simulations of electrolytic potential distribution within a 2 mm half-cell having a central membrane in accordance with an aspect of the present disclosure, in which the hot electrode is on the left and the cold electrode is on the right and the other ion species is diffusing between them.

FIG. 4(c) shows a finite element simulation of electrolytic potential distribution within a 2 mm cell having no central membrane, in which the cold electrode is on the left and the hot electrode is on the right.

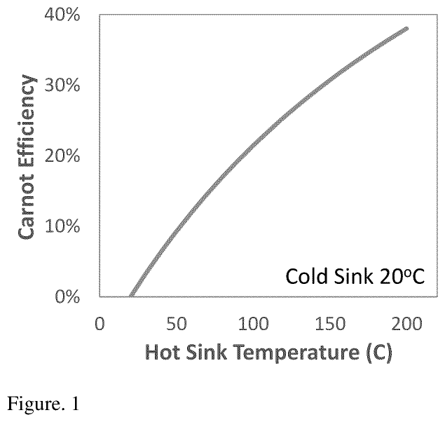

### DETAILED DESCRIPTION

There is a need to achieve overall heat transfer coefficients and heat exchange efficiencies that are large enough to support manageable reactor designs—the balance between ionic conductivity and heat loss needs to be carefully managed. Significant advantages include heat-capturing effectiveness, biocompatibility and conforming to body structure. Additionally, prevention of heat leaks, accidental burnout and incorporation of safety features to prevent accidental shocks are also considered. Finally, many battery-operated devices, such as pace-makers, are equipped with remote transmission systems that help monitor the device-integrity. Power distribution is therefore key to safe functioning of the devices.

The present application includes aspects relating to solid state TEGs, pseudo-supercapacitors, and electrical engineering. Thermo-cells of the present technology may be constructed with standard thin-film techniques that have been applied to many other systems.

That is, conventional versions have not delivered enough power per unit area to be cost competitive with primary sources of energy. In contrast, the present application discloses, through extensive experimentation and simulation, that adding positively and negatively charged membranes to a thermo-cell dramatically increases the Seebeck coefficient. This application discloses a step-change in the Seebeck coefficient for low-temperature heat recovery devices, that is attained via a simple the cell design is simple and does not rely on exotic materials. This technology safely and reliably harvests low grade waste heat to generate electricity.

The designs disclosed in the present application, among other things, enable an efficient and inexpensive construct of a thermo-cell that provides improved efficiency over traditional thermo-cells.

Energy harvesting is an inherent part of sustainable energy resources. Most known sustainable resources, e.g., solar panels or wind turbines, provide energy intermittently and require energy storage, such as batteries or super-capacitors, to supply power in down times. Since heat is prevalent (either from waste, jet engines, motors, developed in solar panel operation, or in wearable electronics), thermoelectric or thermogalvanic (thermo-cell) systems can be used to turn it into useful electrical energy. So far, the efficiency of these cells has not been large, and recent developments in cell efficiency, cell simplicity, and their cost make thermo-cells a potential companion to more expensive energy solutions. The present application discloses a manner of increasing the efficiency of thermo-cells by adding, for example, two interfaces, such that ion diffusion is enhanced towards the electrodes.

Modern ways of living produce heat. Whether from simple notebook batteries, complex jet engines, or heat that is generated by waste, heat is abundant. Making a system that turns it into a useful electrical energy therefore makes a lot of sense. An accompanying system that would involve energy storage, such as super-capacitors, may complete the energy harvesting system. The present disclosure concentrates on thermo-cell-based energy harvesting systems.

Consider solar panels as an example. While such systems generate electricity by turning the sun's radiation into electrical current, an unintended product is heat. The efficiency of a standard solar cell is ca. 20%, where approximately ⅓ of the radiation is reflected, and the remaining part is absorbed in the panels and is turned to heat. Thus, even a low efficiency thermal engine that turns this heat into electricity will increase the overall system efficiency.

As noted above, an enormous amount of heat, equal to 67.5% of U.S. energy consumption in 2019, is available below 150° C. Approximately 30% of this heat could be converted to work at Carnot efficiency. Unfortunately, 150° C. heat cannot be converted to useful work economically with state-of-the-art (SOA) technologies. Recovering only a small fraction of this heat as work would negate the need to build additional generating capacity.

Consider low-grade waste heat. The incumbent technologies for converting low-grade waste heat to electricity are organic Rankine cycles (ORCs) and thermoelectric generators (TEGs). Commercial TEGs use semi-conductor technology and are relatively cheap. However, solid-state TEG technology suffers from requiring a large area in order to harvest low temperature heat, as a consequence of low efficiency.

On the other hand, thermo-cells rely on abundant materials and offer flexible manufacturing and accommodation, for example around cold and hot pipes in buildings. However, the efficiency of thermo-cells is quite low, although efforts to increase it have been made recently. Carnot-relative efficiency, η, in Fe (CN)₆^{3-/4-} thermo-cells has been increased from past values of η=0.6% to current values of η=3.95. This has been achieved by optimization of electrolyte and electrode materials. An even higher power density can be realized by connecting alternating p-type (Seebeck coefficient, Si=+1.02 mV/K in Fe^{2+/3+} PVA gel) and n-type (Seebeck coefficient Si=−1.21 mV/K in Fe(CN)₆^{3-/4-} PVA gel) electrolyte where the resulting thermo-cells were structured electrically in series and thermally in parallel. This arrangement mimics a typical arrangement of thermoelectric cells and is different from the current disclosure.

However, thermo-cells in accordance with the present disclosure show more than a 10-fold power increase compared with previously reported structures. In one aspect, thermo-cells of the present application are compatible with implantable applications because they rely on safe and abundant materials (for example, mostly biocompatible carbons and simple aqueous or non-aqueous electrolytes) and offer flexible manufacturing and installation. Further, the thermo-cells are able to viably convert waste heat available at ≤20° C. to electricity. Aqueous electrolytes include water with a salt, and may include but are not limited to potassium chloride (KCL) or fero/ferri cyanides (persian salts). Examples of non-aqeuous electrolyte include but are not limited to polyethylene glycol (PEG). Alternately, the materials do not have to be biocompatible if sufficiently encased in a biocompatible case (e.g., titanium case).

In one aspect, thermo-cells in accordance with aspects of the present disclosure are ideal for uses where even relatively low temperature differentials are present between a “hot side” and a “cold side”. For example, the thermo-cell may be incorporated into a wearable device, where a temperature differential is present between the human body and the external environment. As such, the wearable device incorporating the thermo-cell constitutes a device or system that is structured and arranged to put one side (i.e., the “hot side”) into thermal communication with the higher temperature side of the temperature differential (e.g., the surface of the wearer's skin) and to put the opposite side (i.e., the “cold side”) into thermal communication with the lower temperature side (e.g., the external environment surrounding the other sides of the wearable device). Other examples of applications include, but are not limited to, an article of clothing, such that the temperature differential of the hot side versus the cold side is between the body heat and the environment.

Combinations of thermogalvanic with thermoelectric cells may be particularly useful, especially in the wearable electronics and medical field. For example, using the redox complex Fe(CN)₆^{3-/4-}, the present inventors demonstrated 17.0 mV/K, or a few hundred mV for temperature difference of 20° C. However, the redox complex is not limited to the above and may include redox-active species such as Fe²⁺/Fe³⁺ in iron oxide (ii, iii).

TABLE 1
Low-grade waste heat recovery technologies

| | Source | | | Seebeck |
|---|---|---|---|---|
| Technology | Temperature | | Status | Coefficient |
| Organic | 100-350° | C. | Mature technology | N/A |
| Rankine Cycle | | | used to recover | |
| | | | geothermal heat. | |
| Thermoelectric | 100-300° | C. | Simple, compact, | 0.2 mV/K |
| Generator | | | light, and efficient | |
| | | | above 150° C. Useful | |
| | | | in harsh and power | |
| | | | deficient | |
| | | | environments. | |
| Thermo-cells | <90° | C. | Simple construction | 1.5 mV/K |
| (SOA) | | | without exotic | |
| | | | materials. Recovery | |
| | | | possible below 100° C. | |
| | | | Can store electric | |
| | | | energy. | |
| Thermo-cells | <90° | C. | Anion/cation | >5 mV/K |

| | |
|---|---|
| (present | exchange membranes |
| disclosure) | increase dU/dT. |

The general concepts of thermal harvesting underpinning aspects of the present disclosure are basically two concepts that one merges: thermo-diffusion and the thermogalvanic effect. Thermo-diffusion is the build-up of an electrical potential difference (from cold to hot) as a result of a gradient of ion concentration in the electrolyte. Specifically, the difference between the diffusion coefficients of ions like Fe²⁺ and Fe³⁺ results in concentration differences, which in turn, are driven by the temperature gradient between electrodes. The chemical potential of electrons in each electrode is denoted as μₑ⁻. Similar to supercapacitors, the voltage drop between the electrodes saturates on the double-layer at the electrode/electrolyte interface. On the other hand, the thermogalvanic effect is the transfer of electrons from ions in the electrolyte to the hot or cold electrodes, which is driven by entropy and potential differences. This continuous process enables a continuous current in the external circuit. That is, the electronic current continues to flow as long as the two electrodes are maintained at different temperatures.

Ions reduced at the cathode transport back to the anode and oxidize. Most SOA systems use the Fe(CN)₆^{3-/4-} ion couple at a relatively high concentration of 0.4 molar. The instant application discloses use of extremely low concentrations of the Fe^{2+/3+} pair generated by adding 0.015 molar of iron-oxide(II, III) to 0.2 molar of oxalic acid or 0.03 molar of iron-oxide(II,III) to 0.4 molar of oxalic acid. Further, most SOA harvesters require inter-electrode distances on the order of 10 cm to operate efficiently, while the thermo-cells of the present disclosure require only a few millimeters (mm) and in some cases less than 1 mm (or 1000 microns) between the electrodes. The addition of the p-type and n-type membrane disposed on a filter may result in an even smaller electrolytic gap.

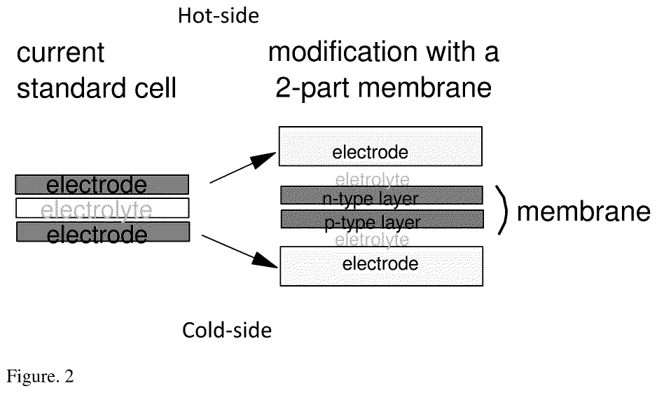

For example, with reference to FIG. 2, the electrolytic gap between the p-n layers is less than 100 microns. As discussed above, aspects of the present disclosure include the addition of positively (p-type) and negatively (n-type) doped membranes. These layers create an electric field gradient between them by selectively transporting one kind of ion over the other. For instance, the thickness of each of the p-type layer and n-type layer may be on the order of 40 microns. Furthermore, the PTFE membrane separating the p-type and n-type layers may have a thickness on the order of 100-200 microns. For example, the p-type and n-type layer may be disposed on the surface of the PTFE membrane for ease of assembly within the thermo-cell. Furthermore, the PTFE membrane separating the p-type and n-type layers, may have a pore size that includes, but is not limited to 0.2 microns to 3 microns. However, this membrane is not limited to PTFE and may be comprised of any filter material that withstands high temperature gradients and is non-reactive with the electrolyte.

Aspects of the present disclosure improve the output of the thermo-cells by increasing the diffusion process towards the electrodes. For example, the structure shown in FIG. 2 can achieve an increase of the related current by a factor of 6 and increasing the related potential by more than 25%. FIG. 2 demonstrates electrodes interfaced with an n-type porous layer (e.g., graphite powder deposited with PEI polymer) and a p-type porous layer (e.g., graphite powder deposited with a PVP polymer). The two interfaces create a local electrical field that promotes ion diffusion in a favorable direction. If the layers are interchanged, the cell voltage may be reversed, which demonstrates the significant effect of providing the interfaces.

Thermo-cells are electrochemical cells like batteries or supercapacitors. Individual cells are comprised of two electrodes separated by an electrolyte. Batteries and supercapacitors spontaneously provide current to an external circuit as long as there is a potential difference (e.g., 1.5 V) between the electrodes. They stop functioning and need recharging when the stored chemical energy and, consequently, the potential difference is exhausted. In contrast, thermo-cells continuously provide current to an external circuit as long as a temperature difference is maintained between a hot electrode and a cold electrode. In that respect, a thermo-cell may provide perpetual electrical energy. Nevertheless, as stated earlier, there is a dire need to improve the efficiency of thermo-cells. Thermo-electrochemical processes in thermo-cells suffer from accumulation of ions and strong reliance on the working environment. It is therefore meaningful to include concepts from solid-state thermoelectric concepts. Most effort to date has been concentrated on material and extraordinarily little on the cell structure itself.

Thermoelectric cells are solid state cells that are based on semiconductor structures. The cells, which are commercially available, are based on diffusion of electronic charges from a hot to a cold electrode. Unlike their electrochemical counterpart, their efficiency is small, and their Seebeck coefficient is of the order of 1 mV/° K. At the same time, the Seebeck coefficient for the electrochemical thermo-cells is much larger, of the order of 2 or more as shown in more detail below.

To make the Seebeck coefficient even larger, the instant application discloses synergies from merging concepts from solid state with electrochemical cells to achieve a Seebeck coefficient, for example, of more than 6. This may be done by including in the cell two passive layers, opposing each other, with a permanent local charge type (e.g., p-type polymeric layer that coats graphitic powder) and a counter charged layer (e.g., n-type polymeric layer that coats a graphitic powder). These two interfaces create a local internal electric field, that enables charge separation. When reaching the electrode (either hot or cold), the ions react and transfer part of their charges to the electrodes. Current voltage values in preliminary cells may reach 0.5 Volts. For example, the ferro-cyanide ions become more negative when departing from the cold electrode, leaving behind positive charges. The local electric field induced between the p-type layer and the n-type layer (in the structural arrangement shown in FIG. 2 promotes the diffusion of these (more negative ions) towards the hot electrode where they will donate their negative charge to the electrode and become more positive. The end result is that the cold electrode becomes more positive and the hot electrode becomes more negative. That potential difference enables the charges to perform electric work in the external circuit.

Furthermore, the p-type polymeric layer that coats a graphitic powder is depositing one surface of the Teflon filter and is placed within the cell. Relatedly, the p-type polymeric layer may coat individual particles of graphitic powder particles. In one aspect, the p-type polymer is diluted in a solvent (e.g., DMF) along with 10% of an additional polymer (e.g., PVDF) to prevent the p-type polymer from dissolving in the aqueous solution. The graphitic powder is added to the mixture to form a slurry which is then deposited onto a surface of the filter membrane (e.g., PTFE filter).

Similarly, the n-type polymeric layer coats a graphitic powder and is depositing a surface of another Teflon filter to be placed against the p-type layer. Relatedly, the n-type polymeric layer may coat individual particles of graphitic powder particles. In one aspect, the n-type polymer is diluted in a solvent (e.g., DMF) along with 10% of an additional polymer (e.g., PVDF) to prevent the n-type polymer from dissolving in the aqueous solution. The graphitic powder is added to the mixture to form a slurry which is then deposited onto another surface of the filter membrane (e.g., PTFE filter).

In one aspect, a thickness of a coating of the p-type membrane is in a monolayer (i.e., approximately the thickness of the diameter of the graphitic powder particles). Similarly, a thickness of a coating of the n-type membrane is also in a monolayer range.

In another aspect, the overall diameter of the P-type coated graphitic powder is about 40 microns (0.04 mm). Similarly, the overall diameter of the carbon particles of the n-type membrane is about 40 microns (0.04 mm).

However, the materials for a positively charged polymeric membrane, or p-type membrane, are not limited to those above and may include polymers such as PVP (polyvinylpyrrolidone), polyacrylic acid (PAA), and polystyrene sulfonate (PSS) as well as biocompatible carbons generally known to a person of ordinary skill.

Furthermore, the materials for a negatively charged polymeric membrane, or n-type membrane, are not limited to the above and may include polymers such as PEI (polyetherimide) and PDMAEMA (poly(2-N-(dimethylaminoethyl) methacrylate) as well as biocompatible carbons generally known to a person of ordinary skill.

For instance, the positively charged PEI on graphitic powder results in a negatively overall charge that attracts positively charged ions. The negatively charged PVP on graphitic powder results in an overall positive charge that attracts negative ions.

In one aspect, the thermo-cell may include the n-type membrane disposed on a cold side of the thermo-cell, and the p-type membrane may be disposed on a hot side of the thermo-cell, or vice versa.

In another aspect, the p-type membrane may include a first p-type membrane and a second p-type membrane; and the n-type membrane may include a first n-type membrane and a second n-type membrane.

In another aspect, the orientation of the p-type and n-type membranes is not limited and may include a thermo-cell having the first p-type membrane, the first n-type membrane, the second n-type membrane, and the second p-type membrane being arranged sequentially from the cold side to the hot side.

In another aspect, the thermo-cell may include the first p-type membrane, the first n-type membrane, the second p-type membrane, and the second n-type membrane being arranged sequentially from the cold side to the hot side.

The Seebeck coefficient resulting from use of thermo-cells in accordance with the present disclosure may be on the order of 16 mV/K or greater. For example, ranges of achievable Seebeck coefficients may include: 1.5 mV/K to 17 mV/K; 5 mV/K to 15 mV/K; 7 mV/K to 12 mV/K; or 9 mV/K to 11 mV/K.

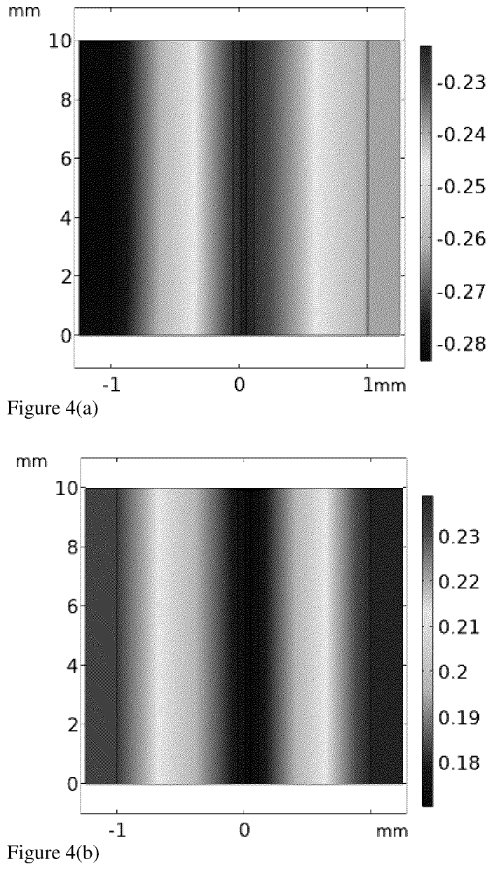

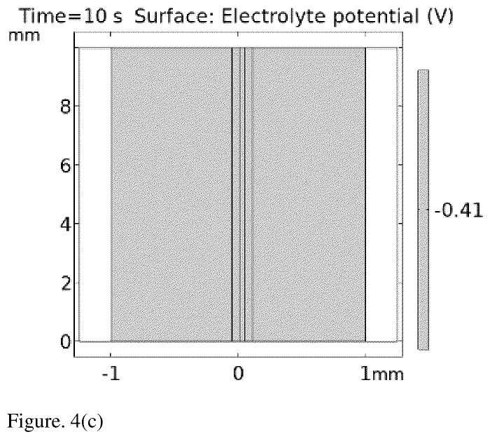

The present inventors used COMSOL Multiphysics®, which is a finite element analysis tool, to analyze charge transfer and heat related effects. The advantage of having the ion-exchange membrane (FIG. 4a,b) is clear when compared to the case without it (FIG. 4c). FIG. 4a shows simulations of electrolytic potential (V) distribution within a 2 mm cell where the cold side is on the left and the hot side is on the right. The presence of the p-n layers exhibits the concentration of local field between the two membranes and an overall large effect on the thermocell when compared to FIG. 4c (without the p-n layers). FIG. 4b shows simulations of electrolytic potential (V) distribution within a 2 mm cell where the cold side is on the right and the hot side is on the left. The presence of the p-n layers exhibits the concentration of local field between the two membranes and the reverse effect on the overall cell's potential distribution compared to FIG. 4a. The overall large change is also shown with respect to FIG. 4c (without the p-n layers). Finally, FIG. 4(c) shows the effect in the cell's potential distribution when no membranes is present; without the p-n membranes the overall potential is rather small to be detected.

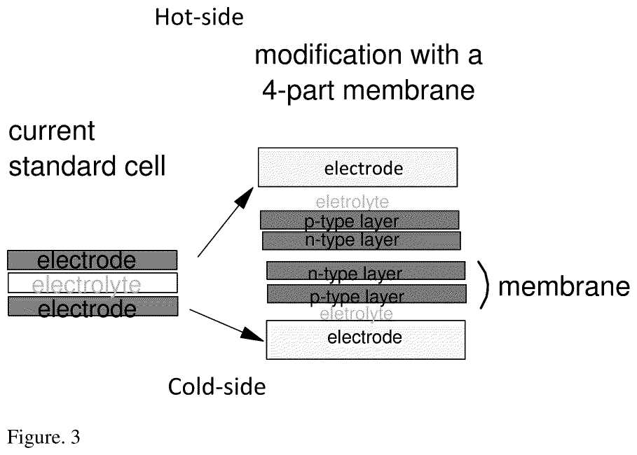

Proof-of-principle experiments and modeling have demonstrated that adding anion and cation exchange membranes (aka p- and n-type membranes) to selectively control ion flow within thermo-cells can, for example, increase the Seebeck coefficient by more than 5× and output power 10× over the SOA. This makes power generation from low-grade waste heat viable. It is believed that configurations of thermo-cells with power densities >1000 μW/cm² for ΔT<20° C. are achievable. Aspects of the present disclosure incorporate different concepts from super-capacitors and semiconductor-based TEGs. The results, for example as shown in Table 3, demonstrate a significant improvement in the cell's construction that dramatically increases the effectiveness of low temperature thermo-cells. That is, by utilizing a thermo-cell design as illustrated in FIGS. 2 and 3, a substantial improvement in electrical output is achieved by forming a constant field gradient that promotes asymmetric ion concentrations near the two reacting electrodes. In one aspect, this is achieved by the addition of a positively charged polymeric membrane—p-type, achieved with mostly polyvinylpyrrolidone (PVP) coated graphite powder with the addition of PVDF (to minimize dissolving the PVP in the aqueous solution), and a negatively charged polymeric membrane (n-type, achieved with mostly polyethylenimine (PEI) coated graphite powder with the addition of PVDF (to minimize dissolving the PEI in the aqueous solution). These layers create an electric field gradient between them because they selectively transport one type of ion over the other (see simulation in FIG. 4). Applicant's refer to this induced electric field gradient concept as “asymmetric thermo-cells.” Due to the efficient internal field created between the membranes' layers, the planar cell length can be on the order of a few millimeters (mm).

Some results are summarized in Tables 2 and 3 below. The samples that led to the results had a sample area of 1 cm² and included: 0.03 M of iron oxide (II, III) in 0.4 M oxalic acid; p, n membranes, i.e., polymer-coated (PVP, PEI, respectively) on graphitic powder on a Teflon membrane, while the electrodes where made of carbon cloth impregnated with conductive carbon powder and 5% PVDF (to hold the powder in place). Note, in this instance there was a structural asymmetry in the cell's configuration. In addition, note the change of direction of the ionic current when the p-layer is interchanged with the n-layer, thus reversing the order of the membranes. Seebeck coefficients larger than 5 mV/K have been routinely achieved with the above arrangement. In further detail, the electrode was made of carbon cloth impregnated with conductive carbon particles glued to the cloth with PVDF. The electrode's thickness was about 200 microns. The lead to and from the electrode was made with carbon cloth as well and was coated with high-temperature epoxy to prevent current shorts. For the 2-part membrane structure examples, a 0.2 micron Teflon filter was used. For the 4-part membrane structures a 3 micron teflon filter was used. The p- and n-layers were polymeric coated 40 micron graphitic powder particles. In the comparative examples “no membrane” refers to a Teflon filter that did not include p- and n-type layers.

### Examples and Comparative Examples

TABLE 2
2-part membranes (Teflon pore size - 0.2 microns)

| | Temperature range (° C.) and | | | Thevenin | |
|---|---|---|---|---|---|
| | membrane orientation | | | power | Seebeck |
| | T_{difference} | Iₛₕₒᵣₜ | Vₒₚₑₙ | Iₛ * Vₒ | Coeff |
| | (° C.) | (mA) | (V) | (W/m²) | (mV/T_{difference}) |
| Example 1: | | | | | |
| n-p | | | | | |
| 31-62 | 31 | 1.79 | 0.342 | 6.1218 | 11.03 |
| 34-75 | 41 | 1.94 | 0.25 | 4.85 | 6.10 |
| 37-81 | 44 | 1.74 | 0.275 | 4.785 | 6.25 |
| Example 2: | | | | | |
| p-n | | | | | |
| 27-60 | 33 | 0.25 | 0.042 | 0.105 | 1.27 |
| 30-72 | 42 | 0.2 | 0.036 | 0.072 | 0.86 |
| 33-81 | 48 | 0.22 | 0.042 | 0.0924 | 0.88 |
| Comparative | | | | | |
| Example 1: | | | | | |
| uncoated | | | | | |
| membranes | | | | | |
| 30-65 | 35 | 0.006 | 0.004 | 0.000258 | 0.12 |
| 33-72 | 39 | 0.014 | 0.008 | 0.001064 | 0.19 |
| 37-80 | 43 | 0.91 | 0.152 | 1.3832 | 3.53 |

In the above examples, a 0.2-micron filter was used and the orientation of the n-type and p-type layers are with respect to the hot side and the cold side of the thermo-cell. For example, in Example 1, the n-type layer was on the hot side whereas the p-type layer was on the cold side. By contrast, in Example 2, the p-type layer was on the hot side whereas the n-type layer was on the cold side. In Example 3, no p-type or n-type membrane layer was present. See also the arrangement illustrated in FIG. 2 for reference. For further reference, and in general, the bottom electrode may be considered hot and the top electrode is cold in the up and down direction. The naming convention in the tables takes this into account. For instance, if the membrane closest to the hot side is p-type, then the order would be “p-n,” as reflected in Example 2 of Table 2.

As is evident from the data of Table 2, Example 1 achieved a significantly greater Thevenin power as well as Seebeck coefficient when compared to Comparative Example 1, which lacked any p-type or n-type membranes. Further, Example 2 shows that reversing the orientation, such that the p-type layer was on the cold side and the n-type layer was on the hot side, may also have significant effects, including lower power and a relatively smaller Seebeck coefficient.

TABLE 3
4-part membranes (Teflon pore size-3 microns)

| | Temperature range (° C.) and | | | Thevenin | |
|---|---|---|---|---|---|
| | membrane orientation | | | power | |
| | T_{difference} | Iₛₕₒᵣₜ | Vₒₚₑₙ | Iₛ * Vₒ | Seebeck Coeff |
| | (° C.) | (mA) | (V) | (W/m²) | (mV/T_{difference}) |
| Example 3: | | | | | |
| p-n-n-p | | | | | |
| 31-61 | 30 | −0.31 | −0.492 | 1.5252 | −16.40 |
| 34-70 | 36 | −0.32 | −0.459 | 1.4688 | −12.75 |
| 38-83 | 45 | −0.33 | −0.487 | 1.6071 | −10.82 |
| Example 4: | | | | | |
| n-p-p-n | | | | | |
| 29-63 | 34 | −0.38 | −0.106 | 0.4028 | −3.12 |
| 32-71 | 39 | −0.33 | −0.095 | 0.3135 | −2.44 |
| 37-82 | 45 | −0.32 | −0.09 | 0.288 | −2.00 |
| Example 5: | | | | | |
| p-n-p-n | | | | | |
| 31-62 | 31 | −0.54 | −0.369 | 1.9926 | −11.90 |
| 34-70 | 36 | −0.52 | −0.345 | 1.794 | −9.58 |
| 38-83 | 45 | −0.51 | −0.327 | 1.6677 | −7.27 |
| Example 6: | | | | | |
| n-p-n-p | | | | | |
| 28-63 | 35 | −0.091 | −0.027 | 0.02457 | −0.77 |
| 33-72 | 39 | −0.04 | −0.018 | 0.0072 | −0.46 |
| 37-83 | 46 | −0.091 | −0.034 | 0.03094 | −0.74 |
| Comparative | | | | | |
| Example 2: | | | | | |
| uncoated | | | | | |
| membrane | | | | | |
| 28-60 | 32 | 0.04 | 0.003 | 0.0012 | 0.09 |
| 33-71 | 38 | −0.15 | −0.12 | 0.18 | −3.16 |
| 37-80 | 45 | −0.21 | −0.09 | 0.189 | −2.00 |

In the above examples, a 3-micron filter was used and the orientation of the n-type and p-type layers are with respect to the cold side and the hot side of the thermo-cell. For example, in Example 3, the orientation of the layers was p-type:n-type:n-type:p-type from the hot side to the cold side. See also the arrangement illustrated in FIG. 3 for reference.

As is evident from the data of Table 3, Example 3 achieved a significantly constant Thevenin power as well as high Seebeck coefficient of 16.4 mV/K.

For instance, Example 4 shows that altering the structural orientation of the p-type and n-type layers, such that the p-type layers are simultaneously on the cold side and the hot side while the n-type layers are disposed therebetween, may also have significant effects, including lower power and a relatively smaller Seebeck coefficient.

For instance, Example 5 shows that altering the structural orientation of the p-type and n-type layers, such that the p-type and n-type layers are alternating with a p-type layer on the cold side and an n-type layer on the hot side, may also have significant effects. For example, Example 5 achieved a higher power overall than Example 3 as well as a high Seebeck coefficient in general.

Further, Example 6 shows that further altering the structural orientation of the p-type and n-type layers may result in low power and a low Seebeck coefficient.

Finally, Comparative Example 2 also lacked any p-type or n-type membranes and demonstrated slight increases in power as the temperature delta increased, although there was a “zig-zag” effect in the Seebeck coefficient.

The inventors have demonstrated that adding anion and cation exchange membranes to selectively control ion flow within thermo-cells can significantly increase the Seebeck coefficient, leading to promising levels of energy recovery at low temperature differences. A series of different redox molecules, different membranes, and reactor configurations are possible using this construct. Any headings and sub-headings utilized in this description are not meant to limit the embodiments described thereunder. Features of various embodiments described herein may be utilized with other embodiments even if not described under a specific heading for that embodiment.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

While exemplary embodiments have been described herein, it is expressly noted that these embodiments should not be construed as limiting, but rather that additions and modifications to what is expressly described herein also are included within the scope of the invention. Moreover, it is to be understood that the features of the various embodiments described herein are not mutually exclusive and can exist in various combinations and permutations, even if such combinations or permutations are not made express herein, without departing from the spirit and scope of the invention.

What is claimed is:

1. A thermo-cell, comprising:
a first electrode and a second electrode defining a space therebetween;
an electrolyte disposed within the space;
a p-type membrane positioned in the space and facing the first electrode; and
an n-type membrane positioned in the space and facing the second electrode;
wherein the p-type membrane and the n-type membrane are physically separated and create an electric field gradient through the space for the selective transport of ions within the electrolyte.

2. The thermo-cell of claim 1,
wherein the p-type membrane is a positively charged polymeric material that includes a first polymer disposed on a first substrate, and
wherein the n-type membrane is a negatively charged polymeric material that includes a second polymer disposed on a second substrate.

3. The thermo-cell of claim 2,
wherein the first polymer includes at least one of polyvinylpyrrolidone (PVP), polyacrylic acid (PAA), and polystyrene sulfonate (PSS), or polyvinylidene fluoride (PVDF) and
wherein the second polymer includes at least one of polyetherimide (PEI), poly(2-N-(dimethylaminoethyl)methacrylate (PDMAEMA), or PVDF.

4. The thermo-cell of claim 2,
wherein the first substrate include a graphite powder layer, and
wherein the second substrate include a graphite powder layer.

5. The thermo-cell of claim 2,
wherein the first polymer is coated on the first substrate layer, and
wherein the second polymer is coated on the second substrate layer.

6. The thermo-cell of claim 1, wherein the p-type membrane and n-type membrane are physically separated by a separating membrane positioned in the space,
wherein the p-type membrane is disposed on a first side of the separating membrane, and
wherein the n-type layer disposed on a second side of the separating membrane.

7. The thermo-cell of claim 1,
wherein the n-type membrane is disposed on a hot side of the thermo-cell, and
wherein the p-type membrane is disposed on a cold side of the thermo-cell.

8. An apparatus including the thermo-cell of claim 7, the thermo cell being arranged such that a temperature difference between the cold side and the hot side of the thermo-cell is in a range of less than 50° C.

9. The thermo-cell of claim 1, wherein a distance between the n-type membrane and p-type membrane is in a range of 100 to 200 microns.

10. The thermo-cell of claim 1, wherein the p-type membrane and n-type membrane are physically separated by a separation distance, and wherein a thickness of the p-type membrane and the n-type membrane is in a range 20%-40% of a thickness of the separation distance.

11. The thermo-cell of claim 7,
wherein the p-type membrane includes a first p-type membrane and a second p-type membrane, and
wherein the n-type membrane includes a first n-type membrane and a second n-type membrane.

12. The thermo-cell of claim 11,
wherein the thermo cell includes the first p-type membrane, the first n-type membrane, the second n-type membrane, and the second p-type membrane arranged sequentially from the hot side to the cold side.

13. The thermo-cell of claim 11,
wherein the thermo cell includes the first p-type membrane, the first n-type membrane, the second p-type membrane, and the second n-type membrane arranged sequentially from the hot side to the cold side.

14. The thermo-cell of claim 1, wherein the electrolyte includes at least one of potassium chloride(KCL), ferro/ferri cyanides, iron oxide (ii,iii), or polyethylene glycol (PEG).

15. The thermo-cell of claim 1, wherein the thermo-cell has a Seebeck coefficient in a range of greater than 1.5 mV/K.

16. The thermo-cell of claim 1, wherein the Seebeck coefficient is in a range of greater than 1.5 mV/K to 17 mV/K.

17. The device of claim 1, wherein the PVP coating on the graphite is disposed on a surface of the graphite in a uniform manner, so as to provide a consistent positive charge distribution across the membrane.

18. The device of claim 1, wherein the PEI coating on the graphite is disposed on a surface of the graphite in a uniform manner, so as to provide a consistent negative charge distribution across the membrane.

19. The device of claim 1, wherein the electric field gradient between the p-type and n-type membranes selectively facilitates the transport of cations through the p-type membrane and anions through the n-type membrane.

20. A system for energy generation comprising:
a plurality of the thermo-cells of claim 1 arranged to be electrically coupled.
